(19) United States
(12) Patent Application Publication
(10) Pub. No.: US 2024/0235329 A1
(43) Pub. Date: Jul. 11, 2024

(54) CLOSED LOOP HEAT EXCHANGER CARTRIDGE SYSTEM INTEGRATED IN A LOWER DRIVE UNIT

(71) Applicant: Forza X1, Inc., Fort Pierce, FL (US)

(72) Inventor: Daniel Norton, Fort Pierce, FL (US)

(21) Appl. No.: 18/404,991

(22) Filed: Jan. 5, 2024

Related U.S. Application Data
(60) Provisional application No. 63/437,411, filed on Jan. 6, 2023.

(51) Int. Cl. H02K 9/19; B63H 20/28; H05K 7/20

(52) U.S. Cl. CPC H02K 9/19; B63H 20/28; H05K 7/20263

(57) ABSTRACT

A closed loop cooling system for an outboard motor is provided. The motor and lower drive unit are cooled with a closed loop heat exchanger that is incorporated into the lower drive. With this type of closed loop heat exchanging system, drive units may become smaller and more efficient in greatly increasing overall efficiency.

### FIELD OF THE INVENTION

The present invention relates to a novel closed loop heat exchanger cartridge system integrated in a lower drive unit for an outboard motor or stern drive system for marine propulsion.

### BACKGROUND OF THE INVENTION

In the realm of marine propulsion systems, outboard boat motors play a pivotal role in powering vessels efficiently and reliably. These motors commonly utilize cooling systems to maintain optimal operating temperatures, ensuring the longevity and performance of their internal combustion engines. Traditional cooling systems often employ open-loop configurations, where water is drawn from the surrounding environment, circulated through the engine for heat exchange, and then expelled back into the water.

While effective, open-loop cooling systems may present challenges, particularly in environments with varying water conditions, such as debris-laden or shallow waters, as well as salt water. Open-loop cooling systems also use raw water from the body of water the motor is in, which contributes to pollution by gathering contaminants from the engine and expelling them into the body of water. The need for enhanced cooling efficiency and adaptability has driven innovation in the field, leading to the development of closed-loop heat exchangers for outboard boat motors.

Closed-loop heat exchangers offer a distinct advantage by isolating the engine cooling circuit from external water sources. This design mitigates the risk of clogging due to debris, minimizes the impact of varying water quality, and provides a more controlled and efficient heat exchange process. By circulating a dedicated coolant within a closed system, the closed-loop heat exchanger optimizes the temperature regulation of the engine, resulting in improved performance, fuel efficiency, and overall reliability.

However, these closed loop heat exchanger systems have several disadvantages as well. For example, they may draw more power and be less efficient than an open cooling system. Moreover, the need exists for a system to cool the fluid which has drawn heat from the motor which leads to inefficiencies, pressure drops and thus increased power draws. A need exists to improve upon these systems, to continue to enhance cooling capabilities, ensuring optimal performance (eliminating drag), decreasing components in the cowling as well as other desired advancements.

The present invention seeks to address the limitations of traditional open-loop cooling systems in outboard boat motors by introducing an innovative closed-loop heat exchanger design. This novel system aims to enhance the thermal management capabilities of outboard motors while addressing challenges associated with environmental factors.

### SUMMARY OF THE INVENTION

The subject matter of this application may involve, in some cases, interrelated products, alternative solutions to a particular problem, and/or a plurality of different uses of a single system or article.

In one aspect, an outboard motor is provided. The outboard motor has a lower drive unit which is formed having a housing with at least one chamber within the housing. A heat exchanger assembly is positioned at least partially within the at least one chamber of the lower drive unit housing. Fluid flow from a closed loop cooling system can flow from heat generating components to the heat exchanger for cooling, and then back to the heat generating components. The heat exchanger assembly has a fluid flow path within it to expose fluid to a surface of the heat exchanger to thereby cool the fluid. Fluid flow from this closed loop heating system is in communication with the fluid flow path.

In another aspect, a boat is provided. The boat has a motor attached thereto and the motor comprises a lower drive unit having a heat exchanger for a closed loop heating system therein. The lower drive unit is formed having a housing with at least one chamber within the housing. A heat exchanger assembly is positioned at least partially within the at least one chamber of the lower drive unit housing. Fluid flow from a closed loop cooling system can flow from heat generating components to the heat exchanger for cooling, and then back to the heat generating components. The heat exchanger assembly has a fluid flow path within it to expose fluid to a surface of the heat exchanger to thereby cool the fluid. Fluid flow from this closed loop heating system is in communication with the fluid flow path.

In yet another aspect, a method of cooling an outboard motor using a closed loop heat exchanger system is provided. The method involves the steps of conveying a cooling fluid between a heat generating component and a heat exchanger, where the heat exchanger is located in a lower drive unit of the motor, which allows a body of water that the outboard motor is in to act as a heat sink, very effectively cooling the cooling fluid of the closed loop system. In the closed loop system, the heat exchanger cools the cooling fluid, which is in turn returned to heat generating components of the outboard motor, heating the cooling fluid, and then the hot cooling fluid is returned to the heat exchanger for cooling again, and this process repeats.

### BRIEF DESCRIPTION OF DRAWINGS

FIG. 1 provides a prior art view of a cooling system for boat motors, particularly outboard boat motors.

FIG. 2 provides a schematic view of an embodiment of the heat exchanger system contemplated herein.

FIG. 3 provides a cutaway view of an embodiment of the present disclosure.

FIG. 4 provides an exploded view of an embodiment of the present disclosure.

FIG. 5 provides a detail cutaway view of an embodiment of the present disclosure.

FIG. 6 provides a side cutaway view of an embodiment of a heat exchanger of the present disclosure.

FIG. 7 provides a perspective view of an embodiment of a heat exchanger of the present disclosure.

### DETAILED DESCRIPTION OF THE INVENTION

The detailed description set forth below in connection with the appended drawings is intended as a description of presently preferred embodiments of the invention and does not represent the only forms in which the present disclosure may be constructed and/or utilized. The description sets forth the functions and the sequence of steps for constructing and operating the invention in connection with the illustrated embodiments.

Generally, the present disclosure concerns a motor such as an outboard motor which uses a closed loop heat exchanger to cool heat generating components. A heat exchanger is located within the lower unit (also called “lower drive unit”) of the motor. The lower unit is known in the art to be the portion of the motor that is in the water and has the propeller. By locating the heat exchanger in the lower unit, it may utilize the body of water that the engine is in as the heat sink, providing highly efficient heat transfer properties.

In one embodiment, a closed loop heat exchanger cartridge system integrated into a lower drive unit comprises: a lower drive unit having a housing, forming at least one chamber in the housing and inserting into the chamber a heat exchanger cartridge assembly. The cartridge assembly has a plurality of elements designed to increase the surface ratio of the cartridge to its volume while also providing a flow path about which a cooling fluid can pass by, through, over and about. The chamber and the heat exchanger cartridge assembly. The cartridge assembly can be configured with an inlet port and an outlet port for receiving a cooling fluid into the cartridge assembly and chamber, while also enable cooling fluid (typically, but not always glycol) to exit the cartridge assembly and chamber.

The chamber formed in the housing can provide or function as a containment surface for the cooling fluid. The chamber is also configured to be in thermal communication with the exterior surface of the housing of the lower drive unit, which when is use is positioned mostly or completely in a body of water. The body of water is designed to be a large heat sink to transfer heat transmitted by the exterior surface of the housing, which heat is transmitted to the exterior surface through the chamber and heat exchanger cartridge assembly, which is extracting heat from the cooling fluid that is extracting heat from heat generating components disposed outside of the lower drive unit. Such heat generating components can include motors, inverters, gear reducing assemblies, batteries, and so forth. In many instances, the lower drive unit itself generates a meaningful amount of heat. By placing the heat exchangers close to these heat generating components in the lower drive unit, there is a shorter flow path required for the cooling fluid and in turn lower energy requirements for the cooling system.

A special designed hub assembly can be attached to the lower drive unit and provide an attachment means to an upper motor unit or cowling, as well as provide various passageways for the cooling fluid to enter into the lower drive unit and exit from the lower drive unit enabling a continuous closed-loop cooling circuit. The special hub can also enable the ability to rotate the lower drive unit in 360 degrees. The cooling fluid is conveyed through the closed loop cooling circuit via, for example, a pump, conduction, and the like.

Attached figures provide additional explanation, diagrams and placements for the various components associated with this cartridge style heat exchanger system.

The present disclosure provides marked improvements in the engine cooling field, allowing the motor and lower drive unit to be cooled with a closed loop heat exchanger that is incorporated into the lower drive. With this type of closed loop heat exchanging system, this can allow drive units to become smaller and more efficient in cooling the drive unit. Further, because there is no raw water intake, the

While generally disclosed as an outboard motor for a boat, the presently disclosed system may be used for any motor, such as an inboard boat motor. Similarly, the motor may be an electric boat motor, or a combustion based motor without straying from the scope of this invention.

Typical heat exchangers in the prior art may use air to cool the engine, using an OEM heat exchanger which is in the upper or cowling area of the motor. The present disclosure eliminates the need for such a device, resulting in more space within the cowling and requiring fewer parts. Further, the overall effectiveness of the cooling system is enhanced for greater heat exchange rates.

The present disclosure, by placing the heat exchanger in the lower drive unit of the motor, which is already in the water, achieves the use of the water as a heat sink without adding extra drag. Prior art systems such as “keel coolers” on workboats are mounted on hulls of boats and, while effective, create a substantial amount of drag, leading to decreased efficiency. These keel cooler structures also require substantial maintenance.

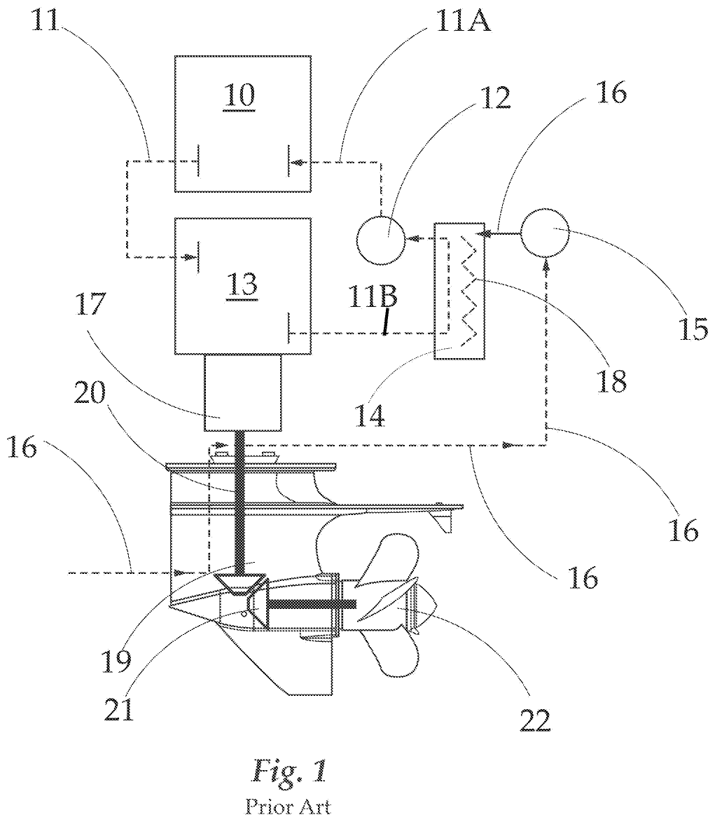

Turning now to FIG. 1, a view of an embodiment of the prior art cooling system for an outboard boat motor is provided. All of the heat exchange flow occurs in the cowling of the motor and relies on raw intake water from a body of water in which the lower drive unit is submerged. The motor has a number of heat-generating components including an inverter 10, motor 13, and gear reducer 17. A glycol flow circulates through these components and to a heat exchanger to remove heat from the components. Glycol flow 11 includes a cool side 11A as well as a hot side 11B and is conveyed via pump 12. A heat exchanger 14 uses cold intake water from the body of water in which the motor is placed to remove heat from the hot side glycol flow 11B to cool it to the cool side flow 11A. Raw intake water 16 is drawn into the system at the lower drive unit 19 and conveyed up into the cowling via pump 15. At an exit of the heat exchanger, the heated raw water flow 18 which has absorbed heat from the hot glycol 11B in the heat exchanger 14 is expelled back into the body of water. The lower drive unit 19 further has an axle 20 and gearing 21 to drive propeller 22.

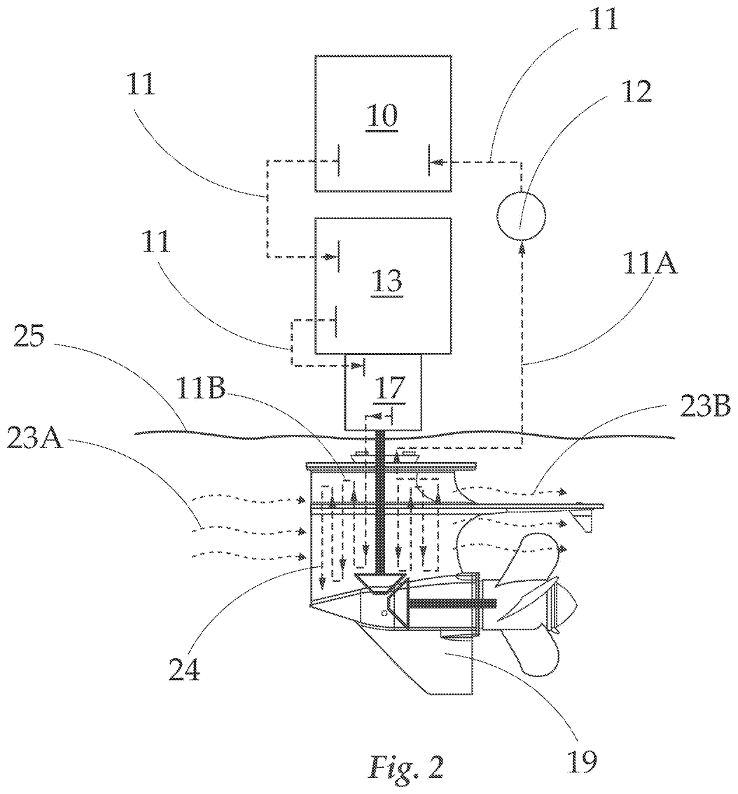

FIG. 2 shows another embodiment of the motor cooling system of the present disclosure. In this view, heat exchange occurs by conduction of heat from heated fluid such as glycol within the lower drive unit and colder outside water, without drawing the outside water into the engine unit. Instead, the heat from the heated fluid conducts through the heat exchanger and shell of the lower drive unit, and is drawn into the colder outside water in which the lower drive unit is submerged. The motor has a number of heat-generating components including an inverter 10, motor 13, and gear reducer 17. In typical embodiments, the motor is an electric motor, though internal combustion engine embodiments may also be cooled using this system. Generally, the present disclosure is suited to electric motor use which may require less cooling than combustion engine embodiments. A glycol flow circulates through these components and to a heat exchanger within the lower drive unit 19 to remove heat from the components. Glycol flow 11 includes a cool side 11A as well as a hot side 11B and is conveyed via pump 12. The hot side glycol flow 11B is conveyed into the lower drive unit into a heat exchanger 24 within the lower drive unit 19 which, in this embodiment, is shown beneath the surface of the body of water 25. Relatively cold outside water 23A contacts the lower drive unit, and draws heat from the heated glycol 11B therein. The heated outside water 23B is then moved away. Cooling operation increases as the motor is moved through the water which increases the water flow 23A over the surface of the lower drive unit 19. Heat exchanger 24 configuration and operation within the lower drive unit 19 may vary without straying from the scope of this disclosure.

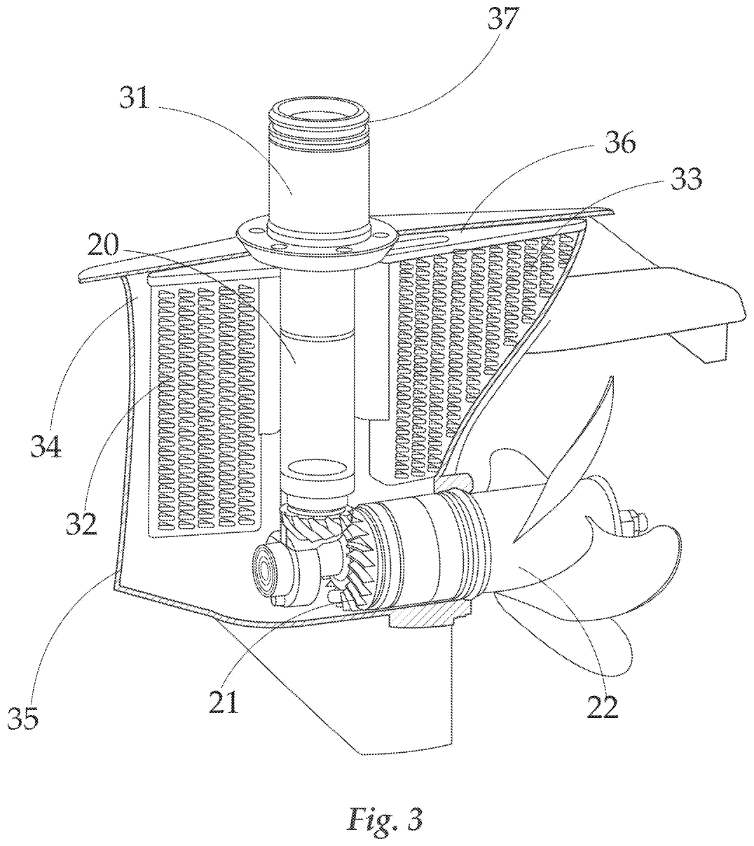

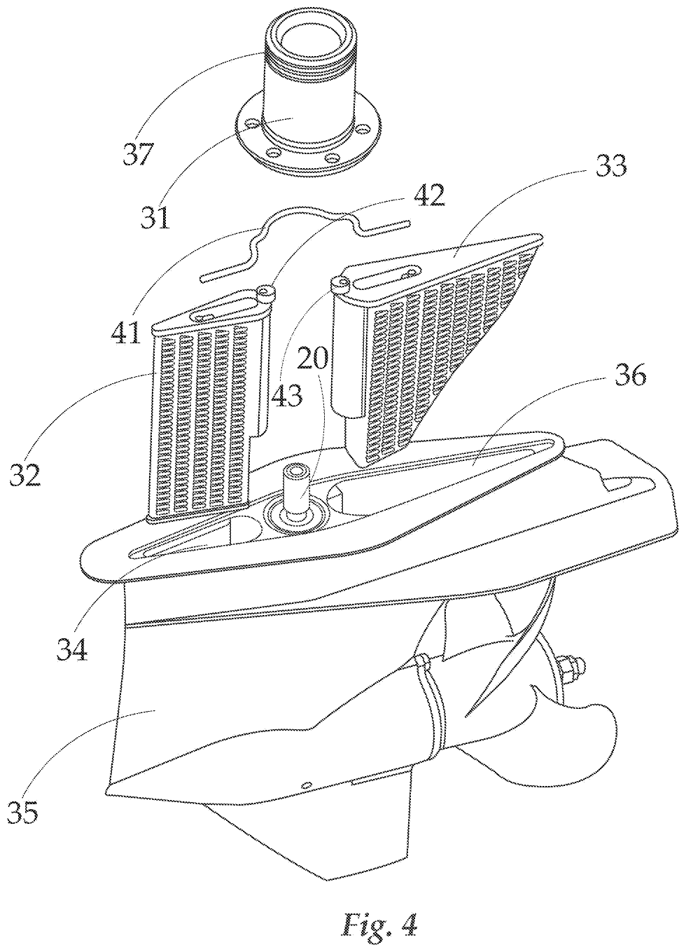

FIG. 3 provides a cutaway view showing an embodiment of a heat exchanger system within the lower drive unit of the outboard motor. FIG. 4 shows a similar embodiment having the components in an exploded view. The lower drive unit 19 has a housing 35 which is exposed to the body of water in operation and defines the chambers 34, 36 which contains the heat exchangers 32, 33, and cooling fluid. Heat exchange occurs across the housing 35 of the lower drive unit 19 which, in operation, is surrounded by the body of water and uses it as a heat sink. The lower drive unit 19 further has a hub 31 which serves multiple purposes. Initially, the hub 31 defines a channel through which the axle 20 may pass to drive the propeller 22. The hub 31 further defines an attachment surface 37 allowing connection of the lower drive unit 19 to the rest of the motor body including the cowling which contains certain motor components (not shown). Further still, the hub 31 defines flow passageways for the heated glycol flow 11B inlet into the lower drive unit 19 and for the cooled glycol flow 11A outlet from the lower drive unit 19, which are shown in further detail in later figures.

As seen in FIG. 4, the hub 31 defines an opening for passage of the axle 20 and connection surface 37 for connecting to the rest of the motor. The heat exchanger cartridges 32, 33 fit within chambers 34, 36 respectively. The front heat exchanger cartridge 32 fits closely into the chamber 34. Heated fluid flows into the inlet port 42 and is conveyed through the heat exchanger cartridge 32. As it is cooled, it exits to connector tube 41 and is conveyed to the rear heat exchanger cartridge 33 which fits into chamber 36. As the fluid is conveyed through cartridge 33, it exits via cooled fluid outlet 43 and is returned to the heat-generating components (not shown) and on through the closed loop. In the embodiment shown, it is noted that the heated fluid enters the front cartridge 32 first. The leading front area of the motor has the coolest water and thus provides the greatest temperature gradient between coolest water and hottest fluid. This may help to increase the heat transfer rate overall. In other embodiments, the hottest fluid may also enter the rear cartridge first, without straying from the scope of this invention.

In the embodiments shown, the heat exchangers 32, 33 fit tightly into their respective chambers 34, 36 to encourage conductive heat transfer between the housing 35 and heat exchanger 32, 33 material. This can be seen in FIG. 4 most easily. In one embodiment, fluid is able to pass through the open structure of the heat exchanger via openings to directly contact the chamber walls. In another embodiment, the fluid is entirely contained within the heat exchanger cartridges.

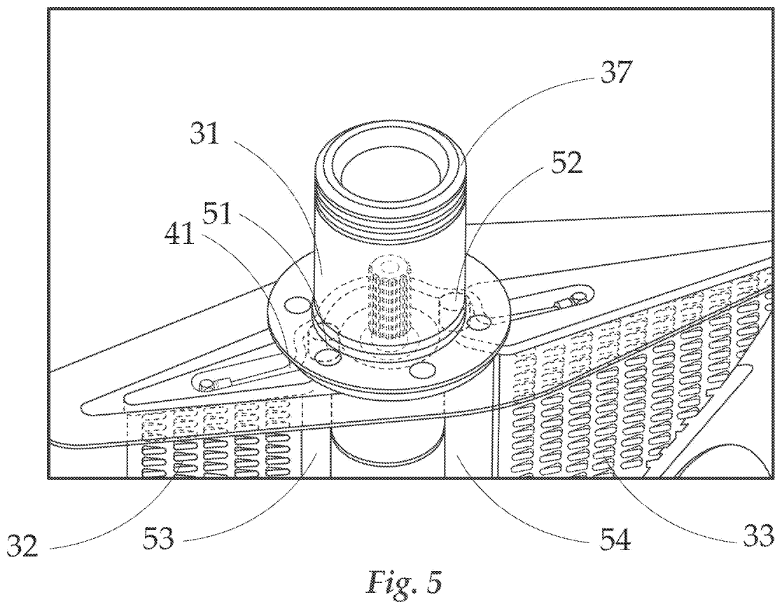

FIG. 5 provides a detail view of the embodiments of FIGS. 3 and 4. The hub 31 defines a hot glycol inlet passageway 51 in communication with the front heat exchanger cartridge 32 and a reservoir 53 therein, as well as a cooled glycol outlet passageway 52 which is in communication with the rear heat exchanger cartridge 33 and reservoir 54 therein. As discussed, the fluid flow comes from and returns to the heat-generating components via pump or other fluid conveyance system in a closed loop.

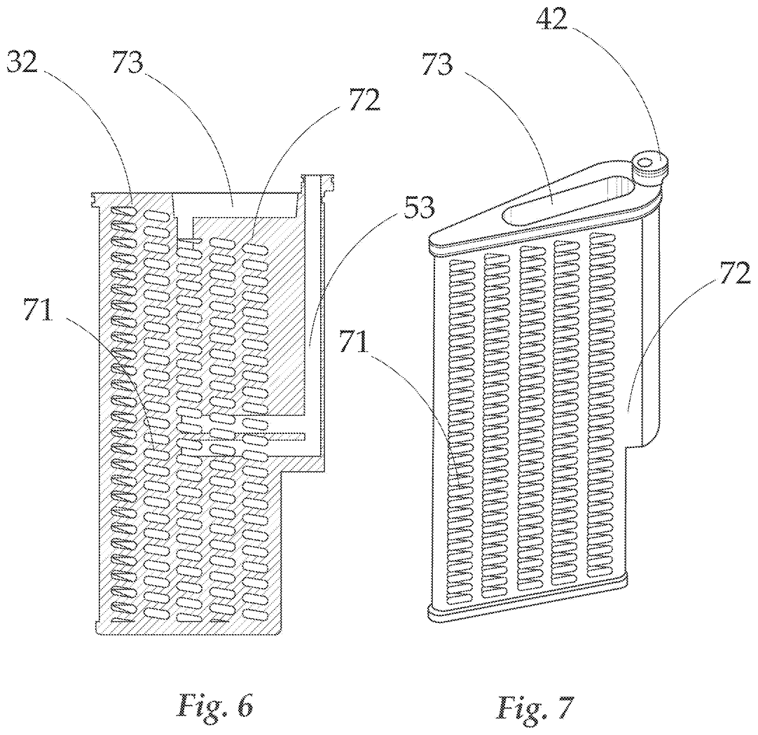

FIGS. 6 and 7 provide views of an embodiment of the heat exchanger cartridge of the present disclosure. This view is of a front heat exchanger cartridge 32. The heat exchanger is formed of a heat-conductive material 72 such as metal, including copper or aluminum, or any other material that is highly heat conductive. A series of openings 71 provide for increased surface area for improved conduction. In one embodiment, the cartridge 32 may be 3D printed, which allows for very intricate and high surface area configurations compared to traditional forming processes such as molding or casting. An inlet reservoir 53 can act as a manifold to distribute fluid flowing into the heat exchanger cartridge 32, and a smaller outlet reservoir 73 provides an area for outlet fluid.

While several variations of the present disclosure have been illustrated by way of example in preferred or particular embodiments, it is apparent that further embodiments could be developed within the spirit and scope of the present disclosure, or the inventive concept thereof. However, it is to be expressly understood that such modifications and adaptations are within the spirit and scope of the present disclosure, and are inclusive, but not limited to the following appended claims as set forth.

What is claimed is:

1. An outboard motor comprising:
a lower drive unit having a housing, the housing forming at least one chamber;
a heat exchanger assembly within the at least one chamber, the heat exchanger assembly having a fluid flow path operable to expose a fluid to a surface of the heat exchanger; and
a closed loop fluid flow in communication with the fluid flow path of the heat exchanger assembly.

2. The outboard motor of claim 1 wherein the outboard motor comprises an electric motor.

3. The outboard motor of claim 1 wherein the heat exchanger assembly comprises an inlet port and an outlet port.

4. The outboard motor of claim 1 wherein the at least one chamber of the housing is a containment surface for the fluid.

5. The outboard motor of claim 1 wherein the at least one chamber is in thermal communication with the exterior surface of the housing of the lower drive unit.

6. The outboard motor of claim 5 wherein the exterior surface of the lower drive unit is formed of metal, and wherein the lower drive unit and housing are formed of metal to provide an effective heat transfer material.

7. The outboard motor of claim 1 wherein the lower drive unit is positioned in a body of water.

8. The outboard motor of claim 1 wherein the heat exchanger assembly comprises a hub assembly attached to the lower drive unit, the hub assembly having an attachment surface to attach to an upper motor unit or cowling of the outboard motor.

9. The outboard motor of claim 8 wherein the hub assembly comprises a passageway for the fluid of the closed loop fluid flow to enter into the lower drive unit and a passageway for the fluid of the closed loop fluid flow to exit from the lower drive unit.

10. The outboard motor of claim 1 wherein the closed loop fluid flow is in communication with at least one heat generating component.

11. The outboard motor of claim 10 wherein the at least one heat generating component is at least one of a motor, inverter, gear reducing assembly, and battery.

12. A boat comprising:
a motor attached to the boat, the motor comprising:
a lower drive unit having a housing, the housing forming at least one chamber;
a heat exchanger assembly within the at least one chamber, the heat exchanger assembly having a fluid flow path operable to expose a fluid to a surface of the heat exchanger; and
a closed loop fluid flow in communication with the fluid flow path of the heat exchanger assembly.

13. The boat of claim 12 wherein the motor comprises an electric motor.

14. The boat of claim 12 wherein the heat exchanger assembly comprises an inlet port and an outlet port.

15. The boat of claim 12 wherein the at least one chamber of the housing is a containment surface for the fluid.

16. The boat of claim 12 wherein the at least one chamber is in thermal communication with the exterior surface of the housing of the lower drive unit.

17. The boat of claim 16 wherein the exterior surface of the lower drive unit is formed of metal, and wherein the lower drive unit and housing are formed of metal to provide an effective heat transfer material.

18. The boat of claim 12 wherein the heat exchanger assembly comprises a hub assembly attached to the lower drive unit, the hub assembly having an attachment surface to attach to an upper motor unit or cowling of the outboard motor.

19. The boat of claim 12 wherein the closed loop fluid flow is in communication with at least one heat generating component wherein the at least one heat generating component is at least one of a motor, inverter, gear reducing assembly, and battery.

20. A method of cooling an outboard motor using a closed loop heat exchanger system comprising the steps of:
conveying a cooling fluid between a heat generating component and a heat exchanger;
cooling the cooling fluid with the heat exchanger;
heating the cooling fluid with the heat generating component; and
cooling the cooling fluid again with the heat exchanger after the step of heating the cooling fluid;
wherein the heat generating component is at least one of a motor, inverter, gear reducing assembly, and battery; and
wherein the heat exchanger is positioned within a lower drive unit of the outboard motor.
